(19) United States
(12) Patent Application Publication
(10) Pub. No.: US 2024/0353321 A1
(43) Pub. Date: Oct. 24, 2024

(54) Combined Spectroscopic Reflectometry And Pattern Recognition Based Measurements Of Semiconductor Structures

(71) Applicant: KLA Corporation, Milpitas, CA (US)

(72) Inventors: David Y. Wang, Santa Clara, CA (US); Shankar Krishnan, Cupertino, CA (US)

(21) Appl. No.: 18/136,772

(22) Filed: Apr. 19, 2023

(51) Int. Cl. G01N 21/31; G01N 21/21; G01N 21/95; G06T 7/00; G06V 10/143; G06V 10/145; G06V 10/147; G06V 10/70; H04N 23/11; H04N 25/71

(52) U.S. Cl. CPC G01N 21/31; G01N 21/211; G01N 21/9505; G06T 7/0004; G06V 10/143; G06V 10/145; G06V 10/147; G06V 10/70; H04N 23/11; H04N 25/71; G06T 2207/20081; G06T 2207/30148

(57) ABSTRACT

Methods and systems for combined Spectroscopic Reflectometry (SR) and Pattern Recognition (PR) based image measurements of semiconductor structures at high throughput are presented herein. Measurements of large pitch targets and thick targets through die with improved fringe contrast, resolution, and spectral fidelity are enabled. A PR based imaging subsystem generates illumination light ranging from visible to short infrared wavelengths. A SR subsystem generates illumination light ranging from the deep ultraviolet to short infrared wavelengths. The SR subsystem includes low Numerical Aperture (NA) optics to realize a relatively large size illumination and collection spot. Both the SR subsystem and the PR based imaging subsystem share the same objective and resolve signals from different depths of a structure under measurement. In some embodiments, a combined machine learning based measurement model estimates values of one or more parameters of interest based on both SR and PR image signals.

### TECHNICAL FIELD

The described embodiments relate to metrology systems and methods, and more particularly to methods and systems for improved measurement of semiconductor structures.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology processes are used at various steps during a semiconductor manufacturing process to detect defects on wafers to promote higher yield. Optical metrology techniques offer the potential for high throughput without the risk of sample destruction. A number of optical metrology based techniques including scatterometry and reflectometry implementations and associated analysis algorithms are commonly used to characterize critical dimensions, film thicknesses, composition, overlay and other parameters of nanoscale structures.

Flash memory architectures are transitioning from two dimensional floating-gate architectures to fully three dimensional geometries. In some examples, film stacks and etched structures are very deep (e.g., up to six micrometers in depth). Such high aspect ratio structures create challenges for film and CD measurements. The ability to measure the critical dimensions that define the shapes of holes and trenches of these structures is critical to achieve desired performance levels and device yield. Current metrology systems struggle to measure critical dimensions and depths of high aspect ratio structures, such as Through-Silicon Via (TSV) structures, due to lack of light penetration and insufficient optical resolution.

In addition, wafer-level semiconductor device packaging is evolving toward three-dimensional packaging architectures. Initially, micro-bump structures, e.g., small copper bumps, provided vertical interconnection between dies. However, the trend is to scale the pitch dimension of interconnect structures down toward 10 micrometers, or less, and attempts to scale micro-bump pitch below 10 micrometers have proven very difficult.

In response to the limitations posed by micro-bump interconnect structures, the industry is moving toward various hybrid bonding techniques that avoid the use of micro-bump structures. Hybrid bonding enables die-to-wafer or wafer-to-wafer packaging via closely spaced copper pads. Hybrid bonding, a.k.a., direct bond interconnect, is a fusion bonding technique employing embedded metal pads at a bond interface that provides a face-to-face connection between die or wafers.

In some embodiments, small copper pads separated by dielectric material are formed on the backside of each die or wafer. The pads associated with two die or wafers are aligned and bonded together by fusion bonding to form small copper-to-copper interconnections separated by dielectric material. These techniques provide relatively high interconnect density, which results in improved electrical performance and bandwidth, decreased standoff height, thinner package size, and lower cost. Hybrid bonding techniques enable three dimensional packages critical to the manufacture of cutting edge electronic devices, e.g., advanced memory cubes.

The relatively small dimensions of the copper pads employed in a cutting edge packaging processes are straining the capabilities of current metrology tools. Measurements of pitch, overlay alignment, surface smoothness, surface profile, etc., associated with hybrid bonding structures are emerging as limitations in current semiconductor manufacturing facilities. The metrology requirements associated with hybrid bonding differ from logic and memory structures in several important ways. First, the illumination and collected light associated with measurements of hybrid bonding structures must penetrate the depth of the die/wafer to reach the backside of the die/wafer where the hybrid bonding structures are located. Second, the thickness and pitch of the hybrid bonding structures is considerably larger, compared to critical dimensions of logic and memory structures. Third, the surface quality of the planar surfaces of the hybrid bonding structures to be fused is critical. Any amount of dishing of the surface profile, surface roughness, or particle contamination will cause voids in the bond lines, and failure of the package.

Many optical techniques suffer from low signal-to-noise ratios (SNRs), as only a small fraction of the illumination light is able to reach the bottom of high aspect ratio features or through the full depth of a die/wafer. Thus, many available high-throughput metrology techniques are unable to reliably perform measurements of high aspect ratio structures or hybrid bonding structures.

Cross-sectional scanning electron microscopy (SEM) is a low throughput, destructive technique that is not suitable for inline metrology. Atomic force microscopy (AFM) is limited the measurement of the top surface and suffers from relatively low throughput. Optical CD metrology currently lacks the ability to measure through the die/wafer with lateral dimensions on the order of 10 micrometers.

U.S. Pat. No. 8,860,937, which is incorporated by reference as if fully set forth herein, describes infrared spectroscopic ellipsometry techniques that are suitable for characterization of high aspect ratio structures. However, the ellipsometric techniques suffer from a limited ability to penetrate through the die/wafer. Existing spectroscopic reflectometry and pattern recognition based imaging systems also suffer from insufficient light penetration to measure hybrid bonding structures, undesirable diffraction order overlap when measuring structure having lateral dimensions on the order of 10 micrometers, insufficient illumination spot size, and limited fringe contrast, sensitivity, and signal fidelity that is detrimental to measurements of thick stacks.

In summary, ongoing reductions in feature size, increasing depths of structural features, and new packaging techniques impose difficult requirements on optical metrology systems. Optical metrology systems must meet high precision and accuracy requirements for increasingly complex targets at high throughput to remain cost effective. In this context, illumination wavelengths, speed of broadband illumination and data collection, and numerical aperture, among other issues, have emerged as critical, performance limiting issues in the design of optical metrology systems suitable for high aspect ratio and hybrid bonding structures. Thus, improved metrology systems and methods to overcome these limitations are desired.

### SUMMARY

Methods and systems for performing combined Spectroscopic Reflectometry (SR) and Pattern Recognition (PR) based image measurements of semiconductor structures at high throughput are presented herein. The combined metrology system is able to perform measurements of large pitch targets and thick targets through die with significantly improved fringe contrast, resolution, and spectral fidelity.

In some embodiments, a pattern recognition based imaging subsystem includes a broadband illumination source that generates illumination light ranging from visible to short infrared wavelengths. In this manner, the pattern recognition based imaging subsystem is able to propagate light through a die or wafer and generate images of hybrid bonding structures located on the backside of a wafer under measurement. The pattern recognition based imaging subsystem also includes a visible to short wavelength infrared (SWIR) two dimensional detector to generate images of relatively large pitch and thick structures.

Similarly, a spectroscopic reflectometer subsystem includes a broadband illumination source that generates illumination light ranging from the deep ultraviolet to short infrared wavelengths. In addition, the spectroscopic reflectometer includes low Numerical Aperture (NA) optics to realize a relatively large size illumination and collection spot to improve fringe contrast, resolution, and signal fidelity from measurements of large pitch structures and thick structures. The spectroscopic reflectometer employs a high speed and high resolution detector to improve spectral resolution and throughput.

In one further aspect, both the spectroscopic reflectometer subsystem and the pattern recognition based imaging subsystem resolve signals from different depths of a structure under measurement. Short wavelength illumination light only penetrates top layers of the structure under measurement, while longer wavelength illumination light penetrates deeper layers of the structure under measurement. In this manner, short wavelength collection light includes information from top layers, while longer wavelength collection light includes information from deeper layers. A spectrometer of the spectral reflectometer subsystem is wavelength resolved, and thus, separates signal information associated with top layers and deeper layers of the structure under measurement. In some embodiments, an imaging detector of the pattern recognition based imaging subsystem generates images at different depths of the structure under measurement by generating different images, each associated with different ranges of collection wavelengths.

In another further aspect, a SR subsystem and a PR imaging subsystem share the same objective. In this manner, both the SR subsystem and the PR subsystem measure the same structure under measurement simultaneously or sequentially without repositioning the wafer.

In some embodiments, measured spectra include different ranges of wavelengths, e.g., ultraviolet, visible, near infrared and mid-infrared wavelengths. In some of these embodiments, a SR subsystem, a PR subsystem, or both, include multiple measurement channels to perform simultaneous measurements of a semiconductor structure with different wavelength light with the same alignment conditions. In this manner, machine errors, such as wavelength errors, are uniformly corrected across all measured wavelengths.

In some embodiments, the methods and systems for combined SR and PR metrology of semiconductor devices described herein are applied to the measurement of high aspect ratio (HAR), large lateral dimension structures disposed on the backside of die, or both. These embodiments enable optical critical dimension (CD), film, and composition metrology for semiconductor devices with HAR structures, overlay, dishing, surface profile, and surface roughness measurements of backside structures such as hybrid bonding structures, and, more generally, measurements of complex devices that suffer from low light penetration into the structure(s) being measured.

In some embodiments, a PR imaging subsystem and a SR subsystem each measure different parameters of interest characterizing a structure under measurement. In some other embodiments, a PR imaging subsystem and a SR subsystem each measure the same parameters of interest characterizing a structure under measurement. In one example, a PR imaging subsystem measures overlay between pads based on one or more two dimensional images of the pads under measurement. In addition, an SR subsystem measures the overlay between pads based on the measured intensity profile, scattering pattern, diffraction pattern, or any combination thereof, induced by the overlay misalignment between the pads.

In some embodiments, SR measurements and PR image based measurements are performed in parallel. In some embodiments, a combined machine learning based measurement model is trained with both SR measurement signals and PR image signals as input. In these embodiments, the trained machine learning based model estimates values of one or more parameters of interest characterizing the structure under measurement based on both SR signals and PR images signals collected from a structure under measurement.

In some embodiments, a SR machine learning based measurement model is trained with SR measurement signals as input and a separate PR machine learning based measurement model is trained with PR image signals as input. In these embodiments, the trained SR machine learning based model estimates values of one or more parameters of interest characterizing the structure under measurement based on SR signals collected from a structure under measurement, and the trained PR machine learning based model estimates values of one or more parameters of interest characterizing the structure under measurement based on PR signals collected from a structure under measurement. In some of these embodiments, the parameters of interest estimated by the trained SR machine learning based measurement model and the trained PR machine learning based measurement model are located at different heights within the structure under measurement.

In general, a combined metrology system may also include additional measurement channels such as a spectroscopic ellipsometer, a scatterometer, or any combination thereof, in addition to SR and PR measurement channels.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 depicts an exemplary combined metrology system 100 for performing spectroscopic reflectometry and pattern recognition based image measurements of semiconductor structures in a reflective mode.

FIG. 2 depicts an exemplary combined metrology system 100 for performing spectroscopic ellipsometry, spectroscopic reflectometry, and pattern recognition based image measurements of semiconductor structures measurements of semiconductor structures in a reflective mode.

FIG. 3 depicts an exemplary high aspect ratio NAND structure 190 that suffers from low light penetration into the structure(s) being measured.

FIG. 4 illustrates a method 200 of performing combined spectroscopic reflectometry and pattern recognition based image measurements of semiconductor structures as described herein.

### DETAILED DESCRIPTION

Reference will now be made in detail to background examples and some embodiments of the invention, examples of which are illustrated in the accompanying drawings.

Methods and systems for performing combined spectroscopic reflectometry and pattern recognition based image measurements of semiconductor structures at high throughput are presented herein. The combined metrology system is able to perform measurements of large pitch targets and thick targets through die with significantly improved fringe contrast, resolution, and spectral fidelity.

In one aspect, a semiconductor metrology system includes a spectroscopic reflectometer and pattern recognition based imaging subsystem suitable for high throughput measurements of high aspect ratio semiconductor structures and hybrid bonding structures. In some embodiments, the pattern recognition based imaging subsystem includes a broadband illumination source that generates illumination light ranging from visible to short infrared wavelengths, e.g., 400 nm to 1700 nm. In this manner, the pattern recognition based imaging subsystem is able to propagate light through a die or wafer and generate images of hybrid bonding structures located on the backside of a wafer under measurement. The pattern recognition based imaging subsystem also includes a visible to short wavelength infrared (SWIR) two dimensional detector to generate images of relatively large pitch and thick structures.

Similarly, the spectroscopic reflectometer includes a broadband illumination source that generates illumination light ranging from the deep ultraviolet to short infrared wavelengths, e.g., 190 nm to 1000 nm. In addition, the spectroscopic reflectometer includes low Numerical Aperture (NA) optics to realize a relatively large size illumination and collection spot to improve fringe contrast, resolution, and signal fidelity from measurements of large pitch structures and thick structures. The spectroscopic reflectometer employs a high speed and high resolution detector to improve spectral resolution and throughput.

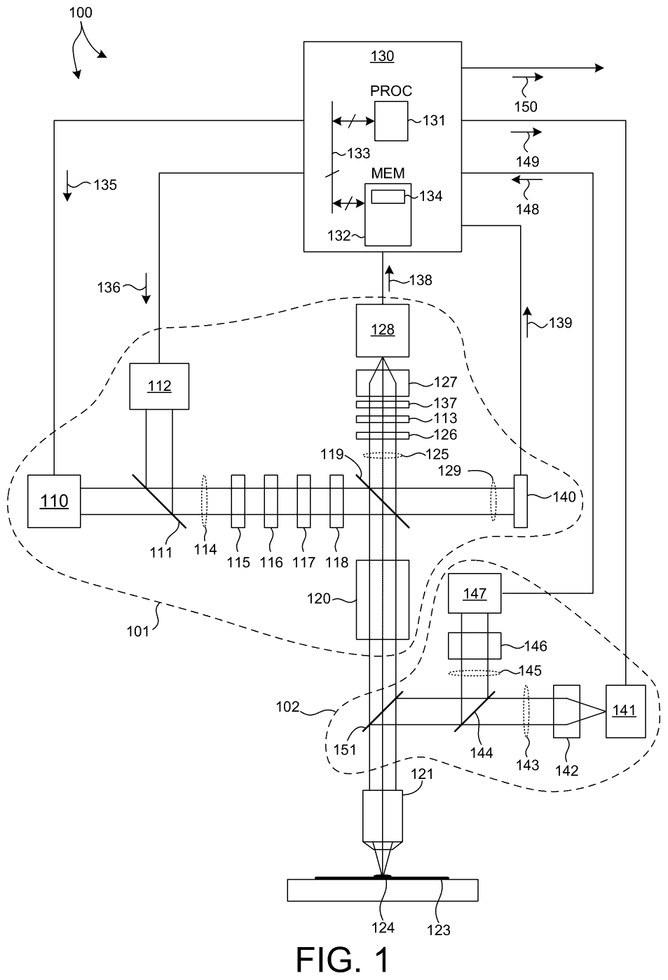

FIG. 1 depicts a simplified diagram of a combined spectroscopic reflectometry (SR) and pattern recognition (PR) based imaging system 100 in one embodiment. As depicted in FIG. 1, the combined system 100 includes a spectroscopic reflectometer subsystem 101 and a pattern recognition imaging subsystem 102, both operable at any wavelength in a range of wavelengths from the visible to short infrared portions of the electromagnetic spectrum.

In the embodiment depicted in FIG. 1, spectroscopic reflectometer subsystem 101 includes a laser sustained plasma (LSP) light source 110 and a mercury lamp light source 112. LSP light source 110 emits illumination light at wavelengths in the deep ultraviolet, visible, near-infrared, and mid-infrared spectra to penetrate through deep structures and through die to illuminate hybrid bonding structures. Typically, an LSP light source emits light in a wavelength range from 170 nanometers to 2500 nanometers. The pump laser of the LSP light source may be continuous wave or pulsed. In the embodiment depicted in FIG. 1, a single LSP pump laser source is employed. However, in general an LSP light source 110 may employ more than one LSP pump laser source to excite photons over different wavelength ranges, thereby enhancing the brightness and power of portions of the plasma spectrum or the entire plasma spectrum. Each LSP pump laser source generates pump light focused by focusing optics to a focal point. The focused pump light sustains a plasma contained by a plasma chamber. The plasma chamber includes one or more exit ports through which the emitted light is transmitted onto the optical system. The plasma generates broadband spectrum light over a wavelength range from vacuum ultra-violet to mid-infrared. A LSP light source can produce significantly more radiance than an arc lamp across the entire wavelength range from 120 nanometers to 20,000 nanometers. As depicted in FIG. 1, control signals 135 are communicated from computing system 130 to control LSP light source 110. In response, LSP light source 110 adjusts its optical output, e.g., flux, spectral range, etc., in accordance with command signals 135.

Mercury lamp light source 112 also emits light over a broad range of wavelengths from 250 nanometers through short infrared wavelengths. Computing system 130 communicates control signal 136 to mercury lamp light source 112. In response, mercury lamp light source 112 adjusts its optical output, e.g., flux, spectral range, etc., in accordance with command signals 136.

Computing system 130 also communicates control signals (not shown) to flip-in mirror 111 to select light source 110 or light source 112 by movement of flip-in mirror 111. In this manner computing system 130 controls which light source provides illumination light to a wafer under measurement.

In general, a combined SR and PR imaging system may include a single light source or a combination of a plurality of broadband or discrete wavelength light sources. The light sources may be selectable and the output of each of these light sources may be controlled by computing system 130 to emit illumination light 114 having desired optical characteristics, e.g., flux, wavelength ranges, etc. The light generated by an illumination source includes a continuous spectrum or parts of a continuous spectrum, from ultraviolet to mid-infrared (e.g., visible to short infrared). In general, a combined SR and PR imaging system may include any of a LSP light source, an arc lamp light source, e.g., a xenon arc lamp, a mercury arc lamp, etc., an incandescent light source, a supercontinuum laser source, an infrared supercontinuum source, a set of lasers, e.g., a set of quantum cascade lasers, an infrared helium-neon laser source, a deuterium lamp, a thermal light source, e.g., globar light source, a quantum cascade laser source, any other suitable light source, or any combination thereof.

In a further aspect, an SR subsystem employs illumination optics having a relatively low numerical aperture (NA) to direct illumination light from one or more illumination sources to the wafer under measurement. In some embodiments, the SR illumination optics limit the numerical aperture of illumination light projected onto a wafer to 0.04 to 0.08. This minimizes overlap, i.e., crosstalk, among diffraction orders over one or more wavelengths. In addition, the relatively low NA enables a relatively large illumination spot size at the wafer, e.g., 20 micrometers to 100 micrometers. The relatively large illumination spot size enables measurement of large pitch structures, such as hybrid bonding structures.

As depicted in FIG. 1, illumination optical elements direct SR illumination light 114 from a selected SR illumination light source toward wafer 123. In the embodiment depicted in FIG. 1, SR illumination light 114 is collimated by illumination optics 115 and filtered by optical filtering elements 116. In addition, SR illumination light 114 is passed through an illumination field stop 117 and pupil aperture 118 to define the shape, size, and divergence of the illumination beam. In general, the illumination optical elements include a field stop, a pupil aperture, and optical elements having reflective focusing power. In addition, the illumination optical elements may also include optional beam conditioning optics, e.g., filters, masks, apodizers, etc.

Beam splitter 119 directs the majority of the SR illumination beam 114 toward polarizing optics 120, and transmits a small portion 129 of the SR illumination beam toward beam monitor 140. Beam monitor 140 communicates signals 139 indicative of the shape, size, and divergence of the illumination beam to computing system 130. Computing system 130 receives the beam monitor signals 139 and generates command signals (not show) communicated to one or more of the illumination optical elements that cause the illumination optical elements to adjust the properties of the illumination beam to match the desired beam properties, e.g., beam shape, size, and divergence.

Polarizing optical device 120 imposes a desired polarization state on the illumination light directed to wafer 123. Polarizing optical device 120 includes one or more polarizing elements and an optional compensator. Polarizing optical device 120 may be fixed, rotatable to different fixed orientations, or continuously rotating at a desired angular velocity. Similarly, the optional compensator may be fixed, rotatable to different fixed orientations, or continuously rotating at a desired angular velocity. In one embodiment, polarizing elements of polarizing optical device 120 include a Magnesium Fluoride Rochon polarizer. In some embodiments, the optional compensator is a quartz waveplate, a Magnesium Fluoride waveplate, a Calcium Fluoride K-prism, or a Calcium Fluoride double Fresnel rhomb. In other embodiments, polarizing optical device 120 is located before beam splitter 119.

After polarization, SR illumination light 114 passes through beam splitter 151 to objective 121. Objective 121 focuses the collimated illumination light onto one or more structures 124 disposed on wafer 123. In some embodiments, the illumination source, e.g., illumination source 112, illumination field stop 117, and wafer 123 are field conjugates. In the embodiment depicted in FIG. 1, the angle of incidence of the focused SR illumination light is at or near normal with respect to wafer 123. However, in general, off-axis illumination may be contemplated within the scope of this patent document.

In some embodiments, the SR illumination optical elements and objective 121 generate an illumination spot size at wafer 123 characterized by a dimension of largest extent of 30-50 micrometers. In some other embodiments, the SR illumination optical elements and objective 121 generate an illumination spot size at wafer 123 characterized by a dimension of largest extent of 20-100 micrometers. In these embodiments, measurements of hybrid bonding structures having a pitch of 10 micrometers or less are enabled.

Objective 121 also collects SR collected light 125 from one or more structures 124 disposed on wafer 123 in response to incident SR illumination light 114. Objective 121 collimates SR collected light 125 and directs the collimated SR collected light 125 towards beam splitter 119. Beam splitter 119 directs SR collected light 125 towards collection optical elements, which, in turn, direct SR collected light 125 onto spectrometer 128. In some embodiments, SR illumination light 114 and SR collected light 125 are collocated at beam splitter 119. However, in some other embodiments, SR illumination light 114 and SR collected light 125 are not collocated at beam splitter 119.

As depicted in FIG. 1, collection optical elements include collection field stop 126, collection pupil aperture 113, and focusing optics 127. Collection field stop 126 defines the size and shape of the collection beam. Collection pupil aperture 113 defines the divergence of the collection beam. In some embodiments, collection pupil aperture 113 limits the numerical aperture of SR collected light 125 from wafer 123 to 0.01 to 0.04. This relatively small collection NA improves fringe contrast, resolution, and spectral fidelity associated with measurements of large pitch targets and thick targets. Focusing optics 127 focus SR collected light 125 at or near a spectrometer slit (not shown) of spectrometer 128. In some embodiments, wafer 123, collection field stop 126, the spectrometer slit of spectrometer 128, and the active surface of the detector of spectrometer 128 are field conjugates.

In general, the collection optical elements include a field stop, a pupil aperture, and optical elements having reflective focusing power. In addition, the illumination optical elements may also include optional beam conditioning optics, e.g., filters, masks, apodizers, etc.

In addition, analyzer 137 is located in the collection optical path between wafer 123 and detector 128. Analyzer 137 includes an analyzer optical element and an optional compensator. Analyzer 137 may be fixed, rotatable to different fixed orientations, or continuously rotating at a desired angular velocity. Similarly, the optional compensator may be fixed, rotatable to different fixed orientations, or continuously rotating at a desired angular velocity. In one embodiment, elements of the analyzer include a Magnesium Fluoride Rochon polarizer. In some embodiments, the optional compensator is a quartz waveplate, a Magnesium Fluoride waveplate, a Calcium Fluoride K-prism, or a Calcium Fluoride double Fresnel rhomb.

Spectrometer 128 includes a spectrometer slit, a dispersive element, one or more optics having reflective focusing power, and a detector. The spectrometer slit receives and directs focused SR collection light 125 to a dispersive element, e.g., a diffraction grating. The dispersive element disperses SR collected light into discrete wavelengths on the active surface of a detector. The detector of spectrometer 128 receives SR collected light 125 from one or more wavelengths, one or more polarization states, or both, at different locations on the active surface of the detector.

In one further aspect, spectrometer 128 resolves signals from different depths of a structure 124 under measurement. For example, short wavelength SR illumination light only penetrates top layers of the structure 124 under measurement, while longer wavelength SR illumination light penetrates deeper layers of the structure 124 under measurement, e.g., hybrid bonding pads. In this manner, short wavelength SR collection light includes information from top layers, while longer wavelength SR collection light includes information from deeper layers. Spectrometer 128 is wavelength resolved, and thus, separates signal information associated with top layers and deeper layers of the structure under measurement.

In some embodiments, the detector of spectrometer 128 is sensitive to vacuum ultraviolet, deep ultraviolet, ultraviolet, visible, and near-infrared light including any wavelength within a range of 120 nanometers to 2.5 micrometers, e.g., 170 nanometers to 1.0 micrometer. In some embodiments, the detector of spectrometer 128 is a charge coupled device (CCD). However, in general, other two dimensional detector technologies may be contemplated (e.g., a position sensitive detector (PSD), a photovoltaic detector, etc.). The detector of spectrometer 128 converts the SR collected light 125 into electrical signals indicative of the spectral intensity of the incident light.

As depicted in FIG. 1, the detector of spectrometer 128 generates detected signals 138 indicative of the optical response of the measured structures on wafer 123 to the illumination light 114. The detector communicates detected signals 139 to computing system 130. Computing system 130 processes the signals from the detector of spectrometer 128 and estimates values 150 of one or more parameters of interest characterizing the measured structure(s) 124 based on detected signals 138.

In some embodiments, the SR measurements described herein include wavelengths ranging from visible to short infrared. However, in some other embodiments, the SR measurements described herein include wavelengths in the mid-infrared and infrared portions of the electromagnetic spectrum.

In the embodiment depicted in FIG. 1, PR imaging subsystem 102 includes a PR light source 141 emitting PR illumination light 143. PR light source 141 generates illumination light 143 including wavelengths ranging from the visible to infrared that penetrate below the top of die.

In some embodiments, PR light source 141 includes one or more LED light sources emitting light in a range of wavelengths from 400 nanometers to 1,700 nanometers. In general, PR imaging subsystem 102 includes one or more broadband sources including, but not limited to a LSP light source, an arc lamp light source, e.g., a xenon arc lamp, a mercury arc lamp, etc., an incandescent light source, a supercontinuum laser source, an infrared supercontinuum source, a set of quantum cascade lasers, an infrared helium-neon laser source, a deuterium lamp, a thermal light source, e.g., globar light source, a quantum cascade laser source, any other suitable light source, or any combination thereof.

As depicted in FIG. 1, control signals 149 are communicated from computing system 130 to control PR light source 141. In response, PR light source 141 adjusts its optical output, e.g., flux, spectral range, etc., in accordance with command signals 149.

PR imaging subsystem 102 employs illumination optics to direct illumination light from one or more illumination sources to the wafer under measurement. As depicted in FIG. 1, PR illumination optical elements direct PR illumination light 143 from PR illumination light source 141 toward wafer 123. In the embodiment depicted in FIG. 1, PR illumination light 143 is collimated by collimating optics 142, then passes through beam splitters 144 and 151 to objective 121. Objective 121 focuses the collimated PR illumination light 143 onto one or more structures 124 disposed on wafer 123.

In some embodiments, PR illumination light 143 is Kohler illuminated at wafer 123 for improved illumination uniformity. In some embodiments, PR illumination light 143 is collocated with SR illumination light 114 at objective 121. In some other embodiments, PR illumination light 143 is not collocated with SR illumination light 114 at objective 121.

Objective 121 also collects PR collected light 145 from one or more structures 124 disposed on wafer 123 in response to incident PR illumination light 143. Objective 121 collimates PR collected light 145 and directs the collimated PR collected light 145 towards beam splitter 151. Beam splitters 151 and 144 direct PR collected light 145 towards collection optical elements, which, in turn, direct PR collected light 145 onto imaging detector 147. In some embodiments, wafer 123 and the active surface of imaging detector 147 are field conjugates.

The collection optical elements include focusing optics 146 that focus PR collection light 145 at or near the active surface of imaging detector 147. Imaging detector 147 detects PR collection light 145 at one or more wavelengths. In some embodiments, imaging detector 147 is a two dimensional CCD camera sensitive to light in a wavelength range spanning the visible to short wavelength infrared, e.g., 400 nanometers to 1,700 nanometers.

In general, imaging detector 147 images PR collection light 145 over one or more wavelength, one or more polarization states, or both.

In one further aspect, imaging detector 147 generates images from different depths of a structure 124 under measurement. For example, short wavelength PR illumination light only penetrates top layers of the structure 124 under measurement, while longer wavelength PR illumination light penetrates deeper layers of the structure 124 under measurement, e.g., hybrid bonding pads. In this manner, short wavelength PR collection light includes information from top layers, while longer wavelength PR collection light includes information from deeper layers. In some embodiments, imaging detector 147 generates images at different depths of the structure 124 under measurement by generating different images, each associated with different ranges of collection wavelengths.

Imaging detector 147 converts the PR collected light 145 into electrical signals indicative of the intensity of the incident light. As depicted in FIG. 1, imaging detector 147 generates PR image signals 148 indicative of the optical response of the measured structures on wafer 123 to PR illumination light 143. Imaging detector 147 communicates PR image signals 148 to computing system 130. Computing system 130 processes the signals from imaging detector 147 using one or more pattern recognition algorithms, and estimates values 150 of one or more parameters of interest characterizing the measured structure(s) 124 based on detected PR image signals 148.

In some embodiments, the PR imaging subsystem described herein is a hyperspectral imaging system. A hyperspectral imaging system images a wafer over a large field of view with high pixel density over a broad range of wavelengths. Image signals collected from a measurement area are detected at a number of pixels. The detected image signals from each pixel are spectrally analyzed separately. Additional details are described in U.S. Pat. No. 10,801,953 to KLA-Tencor Corporation, the content of which is incorporated herein by reference in its entirety.

In some embodiments, an image pixel mapper couples a two dimensional array of collection fiber optical elements into a one dimensional array of pixels at a spectrometer and a hyperspectral detector. The one dimensional array of pixels is aligned in one direction across the active surface of the hyperspectral detector and the spectrometer disperses collected light according to wavelength in a direction orthogonal to the array of image pixels. In this manner, spatial information associated with the image of the measurement area collected over two dimensions is mapped to one dimension at the hyperspectral detector and wavelength information is captured in the orthogonal direction at the hyperspectral detector.

In some embodiments, a hyperspectral imaging detector is configured as a time domain integration (TDI) detector that measures a spatial image of a specimen associated with a particular measurement area over different one or two dimensional arrays of pixels on different portions of the active surface of the hyperspectral TDI detector. Each pixel array is sensitive to different wavelength ranges, polarization states, or both. Furthermore, the measurements of a particular measurement area by each pixel array are integrated electronically to arrive at a spectral response of the spatial image.

In a further aspect, an SR illumination source, a PR illumination source, or both, includes multiple illumination sources, each emitting radiation in a different spectral range. In some embodiments, the multiple illumination sources illuminate the wafer 123 simultaneously. However, in some other embodiments, the multiple illumination sources illuminate the wafer 123 sequentially with a different combination of illumination sources. In this manner, each SR spectral image, PR image, or both, includes signal information associated with a different range of illumination wavelengths and a different penetration depth of the structure 124 under measurement.

In some embodiments, PR illumination source 141 includes multiple LED illumination sources. Each LED illumination source emits radiation in a different spectral range. In some of these embodiments, a set of PR images is detected sequentially and each image of the set of PR images is collected while wafer 123 is illuminated by a different LED illumination source or combination of LED illumination sources. In this manner, each image of the set of PR images includes signal information associated with a different range of illumination wavelengths and a different penetration depth of the structure 124 under measurement.

In another further aspect, a SR subsystem and a PR imaging subsystem share the same objective. In this manner, both the SR subsystem and the PR subsystem measure the same structure under measurement simultaneously or sequentially without repositioning the wafer.

In some embodiments, measured spectra include different ranges of wavelengths, e.g., ultraviolet, visible, near infrared and mid-infrared wavelengths. In some of these embodiments, an SR subsystem, a PR subsystem, or both, include multiple measurement channels to perform simultaneous measurements of a semiconductor structure with different wavelength light with the same alignment conditions. In this manner, machine errors, such as wavelength errors, are uniformly corrected across all measured wavelengths. These features, individually, or in combination, enable high throughput measurements of high aspect ratio structures (e.g., structures having depths of one micrometer or more), backside structures such as hybrid bonding structures, or both, with high throughput, precision, and accuracy.

By measuring with multiple measurement channels of a single metrology system spanning a broad range of illumination wavelengths (e.g., 190 nanometers to 2.5 micrometers), precise characterization of complex three dimensional structures is enabled. In general, relatively long wavelengths penetrate deep into a structure and provide suppression of high diffraction orders when measuring structures with relatively large pitch. Relatively short wavelengths provide precise dimensional information about structures accessible to relatively short wavelengths (i.e., top level layers) as well as relatively small CD and roughness features. In some examples, longer wavelengths enable measurement of dimensional characteristics of targets with relatively rough surfaces or interfaces due to lower sensitivity of longer wavelengths to roughness.

In some embodiments, the methods and systems for combined SR and PR metrology of semiconductor devices described herein are applied to the measurement of high aspect ratio (HAR), large lateral dimension structures disposed on the backside of die, or both. These embodiments enable optical critical dimension (CD), film, and composition metrology for semiconductor devices with HAR structures (e.g., TSV structures, NAND, VNAND, TCAT, DRAM, etc.), overlay, dishing, surface profile, and surface roughness measurements of backside structures such as hybrid bonding structures, and, more generally, for complex devices that suffer from low light penetration into the structure(s) being measured. As described herein, the term “HAR structure” refers to any structure characterized by an aspect ratio that exceeds 2:1 or 10:1, and may be as high as 100:1, or higher.

More specifically, a combined semiconductor metrology system including a SR subsystem and a PR based imaging subsystem enables high throughput characterization of several classes of semiconductor structures that are currently inadequately measured. Measurements include: 1) Measurement of critical dimensions of three dimensional semiconductor packages; 2) Measurement of epitaxial film layers; 3) Measurement of high aspect ratio structures employed in DRAM manufacturing, in particular, the storage node; 4) Measurement of thick, opaque layers such as amorphous carbon films, and 5) Measurement of channel holes, tungsten recess, and other critical metrology challenges in three dimensional NAND manufacturing.

In addition, a combined semiconductor metrology system including a SR subsystem and a PR based imaging subsystem enables high throughput characterization of several emerging classes of semiconductor structures that are currently inadequately measured. These measurements include 1) Measurement of critical dimensions and shape of through silicon vias (TSVs); 2) Measurement of critical dimensions and shape of DRAM capacitor structures; 3) Measurement of silicon/silicon carbide epitaxy and composition; 4) Measurement of films employed in three dimensional NAND hard mask layers (e.g., amorphous carbon layers); and 5) Measurement of three dimensional NAND Tungsten Recess and Channel hole profiles.

In some embodiments, a PR imaging subsystem and a SR subsystem each measure different parameters of interest characterizing a structure under measurement. In some other embodiments, a PR imaging subsystem and a SR subsystem each measure the same parameters of interest characterizing a structure under measurement. In one example, a PR imaging subsystem measures overlay between pads based on one or more two dimensional images of the pads under measurement. In addition, an SR subsystem measures the overlay between pads based on the measured intensity profile, scattering pattern, diffraction pattern, or any combination thereof, induced by the overlay misalignment between the pads.

In another further aspect, measurements performed by one or more spectroscopic reflectometer measurement channels are combined with measurements performed by a pattern recognition based imaging channel to characterize high aspect ratio structures or hybrid bonding structures. In some embodiments, physics based modelling techniques are employed to estimate values of parameters of interest. In some other embodiments, machine learning based modelling techniques are employed to estimate values of parameters of interest.

In some embodiments, SR measurements and PR image based measurements are performed independently. In some of these embodiments, SR measurements and PR image based measurements are employed to estimate values of different parameters of interest. In other embodiments, SR measurements and PR image based measurements are employed to estimate values of the same parameters of interest.

In some examples, measurements of parameters of interest are performed based on SR and PR imaging techniques including single target techniques, multi-target techniques and feedforward techniques. Accuracy of measured parameters may be improved by any combination of feed sideways analysis, feed forward analysis, and parallel analysis. Feed sideways analysis refers to taking multiple data sets on different areas of the same specimen and passing common parameters determined from the first dataset onto the second dataset for analysis. Feed forward analysis refers to taking data sets on different specimens and passing common parameters forward to subsequent analyses using a stepwise copy exact parameter feed forward approach. Parallel analysis refers to the parallel or concurrent application of a non-linear fitting methodology to multiple datasets where at least one common parameter is coupled during the fitting.

Multiple tool and structure analysis refers to a feed forward, feed sideways, or parallel analysis based on regression, a look-up table (i.e., “library” matching), or another fitting procedure of multiple datasets. Exemplary methods and systems for multiple tool and structure analysis is described in U.S. Pat. No. 7,478,019, issued on Jan. 13, 2009, to KLA-Tencor Corp., the entirety of which is incorporated herein by reference.

In some embodiments, SR measurements and PR image based measurements are performed in parallel. In some embodiments, a combined machine learning based measurement model is trained with both SR measurement signals and PR image signals as input. In these embodiments, the trained machine learning based model estimates values of one or more parameters of interest characterizing the structure under measurement based on both SR signals and PR images signals collected from a structure under measurement.

In some embodiments, a SR machine learning based measurement model is trained with SR measurement signals as input and a separate PR machine learning based measurement model is trained with PR image signals as input. In these embodiments, the trained SR machine learning based model estimates values of one or more parameters of interest characterizing the structure under measurement based on SR signals collected from a structure under measurement, and the trained PR machine learning based model estimates values of one or more parameters of interest characterizing the structure under measurement based on PR signals collected from a structure under measurement. In some of these embodiments, the parameters of interest estimated by the trained SR machine learning based measurement model and the trained PR machine learning based measurement model are located at different heights within the structure under measurement.

In general, a combined metrology system may also include additional measurement channels such as a spectroscopic ellipsometer, scatterometer, or any combination thereof, in addition to the SR and PR measurement channels described with reference to FIG. 1.

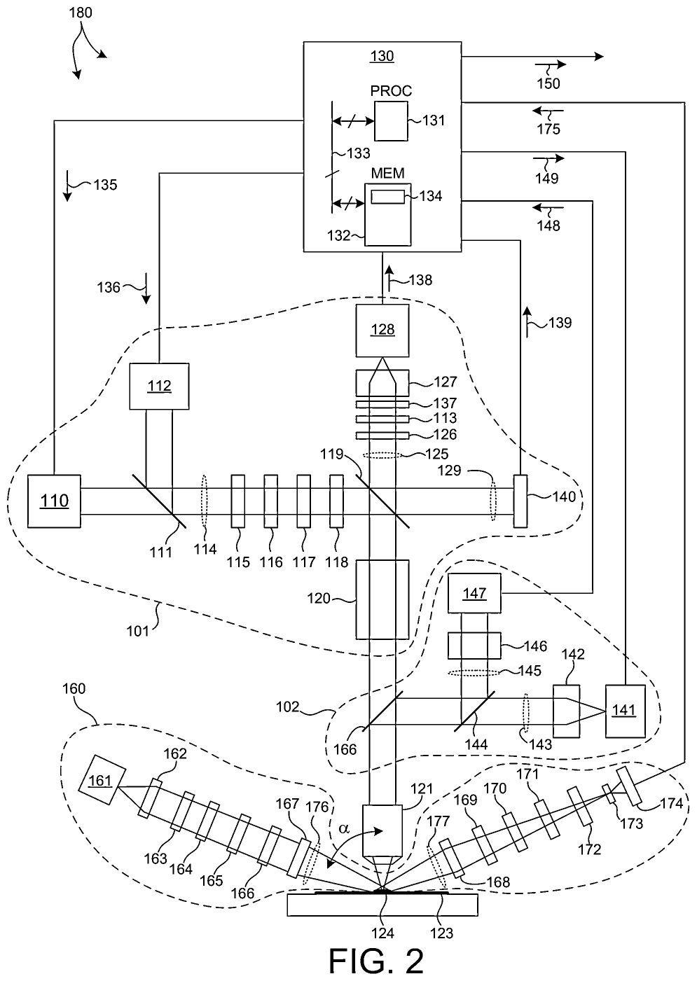

FIG. 2 depicts a metrology system 180 including a spectroscopic reflectometer (SR) measurement channel and a pattern recognition (PR) image based measurement channel as described with reference to FIG. 1, and a spectroscopic ellipsometer (SE) measurement channel. Like numbered elements are analogous to those described with reference to FIG. 1. In the embodiment depicted in FIG. 2, the measurement spot of the PR imaging subsystem, the SR subsystem, and the SE subsystem are co-located. In some other embodiments, the measurement spots are not co-located.

As depicted in FIG. 2, a SE measurement subsystem 160 includes an SE illumination source 161. The SE illumination source may be a separate illumination source or the same illumination source as SR subsystem 101, PR imaging subsystem 102, or both.

In some embodiments, SE illumination source 161 emits illumination wavelengths ranging from 120 nanometers to 2,500 nanometers. In some embodiments, SE illumination source 161 is a LSP light source.

As depicted in FIG. 2, SE illumination light 176 is received by source optics 162. SE illumination light 176 passes through optional optical filters 163, polarizing component 164, field stop 165, aperture stop 166, and illumination optics 167. The one or more optical filters 163 control light level, spectral output, or both, from the illumination subsystem. In some examples, one or more multi-zone filters are employed as optical filters 163. Polarizing component 164 generates the desired polarization state exiting the illumination subsystem. In some embodiments, the polarizing component is a polarizer, a compensator, or both, and may include any suitable commercially available polarizing component. The polarizing component can be fixed or rotatable to different fixed positions. Although the illumination subsystem depicted in FIG. 2 includes one polarizing component, the illumination subsystem may include more than one polarizing component. Field stop 165 controls the field of view (FOV) of the illumination subsystem and may include any suitable commercially available field stop. Aperture stop 166 controls the numerical aperture (NA) of the illumination subsystem and may include any suitable commercially available aperture stop. Light from SE illumination source 161 is directed through illumination optics 167 to be focused on one or more structures on wafer 123 at an oblique angle, a. The illumination subsystem may include any type and arrangement of optical filter(s) 163, polarizing component 164, field stop 165, aperture stop 166, and illumination optics 167 known in the art of spectroscopic ellipsometry.

As depicted, in FIG. 2, the beam of illumination light 176 passes through optical filter(s) 163, polarizing component 164, field stop 165, aperture stop 166, and illumination optics 167 as the beam propagates from the illumination source 161 to wafer 123. Beam 176 illuminates a portion of wafer 123 over a measurement spot.

SE subsystem 160 also includes collection optics configured to collect light generated by the interaction between the one or more structures under measurement and the incident illumination beam 176. A beam of collected light 177 is collected from the measurement spot by collection optics 168. Collected light 177 passes through collection aperture stop 169, polarizing element 170 and field stop 171 of the collection optics subsystem.

Collection optics 168 includes any suitable optical elements to collect light from the one or more structures formed on wafer 123. Collection aperture stop 169 controls the NA of the collection optics subsystem. Polarizing element 170 analyzes the desired polarization state. The polarizing element 170 is an analyzer or a compensator. The polarizing element 170 can be fixed or rotatable to different fixed positions. Although the collection subsystem depicted in FIG. 2 includes one polarizing element, the collection subsystem may include more than one polarizing element. Collection field stop 171 controls the FOV of the collection subsystem. The collection subsystem takes light from wafer 123 and directs the light through collection optics 168 and polarizing element 170 to be focused on collection field stop 171. In some embodiments, collection field stop 171 is used as a spectrometer slit for the spectrometers of the detection subsystem. However, collection field stop 171 may be located at or near a spectrometer slit 172 of the spectrometers of the detection subsystem.

The collection subsystem may include any type and arrangement of collection optics 168, aperture stop 169, polarizing element 170, and field stop 171 known in the art of spectroscopic ellipsometry.

In the embodiment depicted in FIG. 2, the collection optics subsystem directs light to a spectrometer of the detection subsystem. The detection subsystem generates output responsive to light collected from the one or more structures illuminated by the illumination subsystem. In the embodiment depicted in FIG. 2, collected light 177 passes through spectrometer slit 172 and is incident on diffractive element 173. Diffractive element 173 is configured to spatially separate wavelengths of the incident light at the light sensitive surface of detector 174. In one example, detector 174 is a charge coupled device (CCD) sensitive to vacuum ultraviolet and ultraviolet (e.g., light having wavelengths between 120 nanometers and 400 nanometers). In another example, detector 174 is a charge coupled device (CCD) sensitive to deep ultraviolet to short infrared (e.g., light having wavelengths between 170 nanometers and 1,000 nanometers). In another example, detector 174 is a near infrared sensor (e.g., sensitive to light having wavelengths between 850 nanometers and 2500 nanometers).

Metrology system 180 also includes computing system 130 configured to receive detected signals 175 including the spectral response of wafer 123 to VUV, DUV, visible, near-infrared, and mid-infrared illumination. Furthermore, computing system 130 determines an estimate 150 of a value of a parameter of interest of the measured structure(s) based on detected signals 138, 148, and 175. In some embodiments, measurement signals 138, 148, and 175 are collected simultaneously.

FIGS. 1 and 2 depict embodiments of a combined metrology system operating in a reflective mode (i.e., the illumination light is provided to the wafer on the same side as the light collected from the wafer). In other embodiments, a combined metrology system is configured to operate in a transmission mode (i.e., the illumination light is provided to the wafer on the opposite side as the light collected from the wafer).

In some embodiments, the SR subsystem described herein employ off-axis illumination, collection, or both, to reject measurement signals generated by reflections from the bottom of the underlying substrate. In these embodiments, the illumination, collection, or both, are arranged at near normal incidence, but specifically avoiding normal incidence (AOI=zero degrees). In some embodiments, normal illumination is employed, but an obscuration mask in the collection path at or near the collection aperture stop or its conjugates, is employed to block the central rays over the numerical aperture such that the back side reflection is not admitted into the measurement optics. This approach enables normal illumination incidence, but suffers from possible disadvantages such as a centrally obscured pupil, light loss, and algorithmic complexity. In some other embodiments, and obscuration is located in the illumination path.

As depicted in FIGS. 1 and 2, the illustrated SR measurement channel includes a polarizer and an analyzer. However, in general, it is contemplated that any measurement channel may include, or not include, an illumination polarizer, a collection analyzer, an illumination compensator, a collection compensator, in any combination, to perform measurements of the polarized reflectivity of the sample, unpolarized reflectivity of the sample, or both.

In some embodiments, one or more measurement channels of the metrology systems described herein are configured to measure the wafer at different azimuth angles, in addition to different ranges of wavelength and angle of incidence. In some embodiments, a combined metrology system as described herein is configured to perform measurements of the wafer at azimuth angles of zero and ninety degrees relative to the metrology target. In some embodiments, the metrology system is configured to measure wafer reflectivity over one or more wavelength ranges, one or more AOI ranges, and one or more azimuth angles simultaneously.

Although FIGS. 1 and 2 describe specific embodiments of a combined metrology system including a SR subsystem and a PR imaging based subsystem, in general, the measurement techniques described herein apply to any combination of SR and PR imaging based metrology subsystems. Exemplary SR subsystems include, but are not limited to, polarized SR, unpolarized SR, Mueller matrix SR, spectroscopic scatterometry, scatterometry overlay, angle resolved reflectometry, polarization resolved reflectometery, beam profile reflectometry, etc.

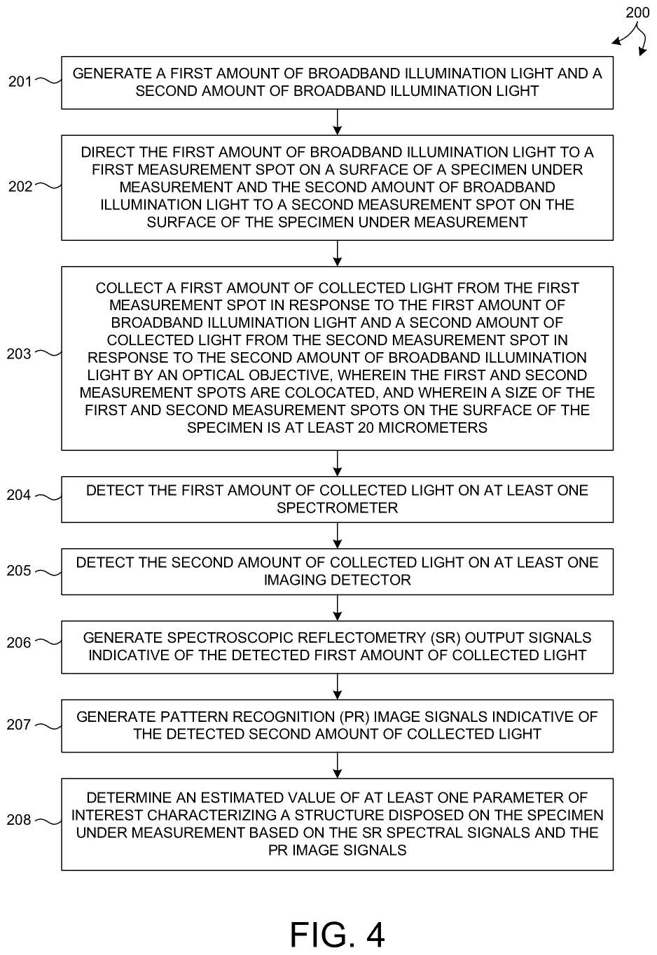

FIG. 4 illustrates a method 200 of performing combined SR and PR measurements in at least one novel aspect. Method 200 is suitable for implementation by a metrology system such as metrology systems 100 and 200, illustrated in FIGS. 1 and 2, respectively, of the present invention. In one aspect, it is recognized that data processing blocks of method 200 may be carried out via a pre-programmed algorithm executed by one or more processors of computing system 130, or any other general purpose computing system. It is recognized herein that the particular structural aspects of metrology systems 100 and 200 do not represent limitations and should be interpreted as illustrative only.

In block 201, a first amount of broadband illumination light and a second amount of broadband illumination light are generated by at least one illumination source.

In block 202, the first amount of broadband illumination light is directed to a first measurement spot on a surface of a specimen under measurement, and the second amount of broadband illumination light is directed to a second measurement spot on the surface of the specimen under measurement.

In block 203, a first amount of collected light is collected from the first measurement spot in response to the first amount of broadband illumination light, and a second amount of collected light is collected from the second measurement spot in response to the second amount of broadband illumination light by an optical objective. The first and second measurement spots are collocated. The size of the first and second measurement spots on the surface of the specimen is at least 20 micrometers.

In block 204, the first amount of collected light is detected on at least one spectrometer.

In block 205, the second amount of collected light is detected on at least one imaging detector.

In block 206, Spectroscopic Reflectometry (SR) output signals indicative of the detected first amount of collected light are generated.

In block 207, Pattern Recognition (PR) image signals indicative of the detected second amount of collected light are generated.

In block 208, an estimated value of at least one parameter of interest characterizing a structure disposed on the specimen under measurement is determined based on the SR spectral signals and the PR image signals.

In a further embodiment, systems 100 and 180 include one or more computing systems 130 employed to perform measurements semiconductor structures based on combined SR and PR imaging measurement data collected in accordance with the methods described herein. The one or more computing systems 130 may be communicatively coupled to the spectrometer 128 and imaging detector 147. In one aspect, the one or more computing systems 130 are configured to receive measurement data associated with measurements of the structure of the specimen under measurement.

It should be recognized that one or more steps described throughout the present disclosure may be carried out by a single computer system 130 or, alternatively, a multiple computer system 130. Moreover, different subsystems of systems 100 and 200 may include a computer system suitable for carrying out at least a portion of the steps described herein. Therefore, the aforementioned description should not be interpreted as a limitation on the present invention but merely an illustration.

In addition, the computer system 130 may be communicatively coupled to the spectrometers and imaging detectors in any manner known in the art. For example, the one or more computing systems 130 may be coupled to computing systems associated with the spectrometers and imaging detectors. In another example, each of the spectrometers and imaging detectors may be controlled directly by a single computer system coupled to computer system 130.

The computer system 130 of metrology systems 100 and 200 may be configured to receive and/or acquire data or information from the subsystems of the system (e.g., spectrometers, imaging detectors, and the like) by a transmission medium that may include wireline and/or wireless portions. In this manner, the transmission medium may serve as a data link between the computer system 130 and other subsystems of systems 100 and 200.

Computer system 130 of metrology systems 100 and 200 may be configured to receive and/or acquire data or information (e.g., measurement results, modeling inputs, modeling results, reference measurement results, etc.) from other systems by a transmission medium that may include wireline and/or wireless portions. In this manner, the transmission medium may serve as a data link between the computer system 130 and other systems (e.g., memory on-board metrology system 100, external memory, or other external systems). For example, the computing system 130 may be configured to receive measurement data from a storage medium (i.e., memory 132 or an external memory) via a data link. For instance, spectral results obtained using the spectrometers described herein may be stored in a permanent or semi-permanent memory device (e.g., memory 132 or an external memory). In this regard, the spectral results may be imported from on-board memory or from an external memory system. Moreover, the computer system 130 may send data to other systems via a transmission medium. For instance, a measurement model or an estimated parameter value 150 determined by computer system 130 may be communicated and stored in an external memory. In this regard, measurement results may be exported to another system.

Computing system 130 may include, but is not limited to, a personal computer system, mainframe computer system, cloud-based computer system, workstation, image computer, parallel processor, or any other device known in the art. In general, the term “computing system” may be broadly defined to encompass any device having one or more processors, which execute instructions from a memory medium.

Program instructions 134 implementing methods such as those described herein may be transmitted over a transmission medium such as a wire, cable, or wireless transmission link. For example, as illustrated in FIG. 1, program instructions 134 stored in memory 132 are transmitted to processor 131 over bus 133. Program instructions 134 are stored in a computer readable medium (e.g., memory 132). Exemplary computer-readable media include read-only memory, a random access memory, a magnetic or optical disk, or a magnetic tape.

In some examples, the measurement models are implemented as an element of a SpectraShape® optical critical-dimension metrology system available from KLA-Tencor Corporation, Milpitas, California, USA. In this manner, the model is created and ready for use immediately after the spectra are collected by the system.

In some other examples, the measurement models are implemented off-line, for example, by a computing system implementing AcuShape® software available from KLA-Tencor Corporation, Milpitas, California, USA. The resulting, trained model may be incorporated as an element of an AcuShape® library that is accessible by a metrology system performing measurements.

In another aspect, the methods and systems for combined metrology of semiconductor devices described herein are applied to the measurement of high aspect ratio (HAR) structures, large lateral dimension structures, or both. The described embodiments enable optical critical dimension (CD), film, and composition metrology for semiconductor devices including hybrid bonding structures, through silicon vias, three dimensional NAND structures, such as vertical-NAND (V-NAND) structures, dynamic random access memory structures (DRAM), etc., manufactured by various semiconductor manufacturers such as Samsung Inc. (South Korea), SK Hynix Inc. (South Korea), Toshiba Corporation (Japan), and Micron Technology, Inc. (United States), etc. These complex devices suffer from low light penetration into the structure(s) being measured.

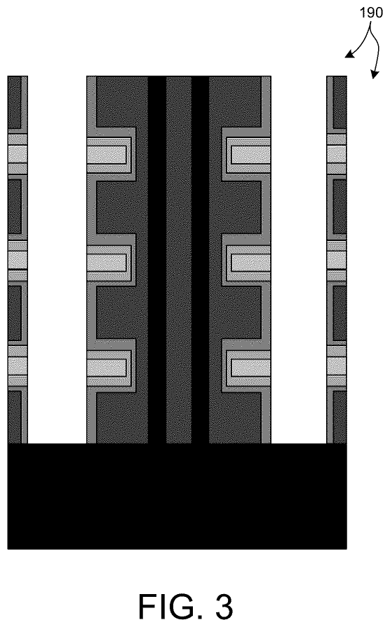

FIG. 3 depicts an exemplary high aspect ratio NAND structure 190 that suffers from low light penetration into the structure(s) being measured. A combined metrology system as described herein is suitable for measurements of these high-aspect ratio structures.

In yet another aspect, the measurement results described herein can be used to provide active feedback to a process tool (e.g., lithography tool, etch tool, deposition tool, etc.). For example, values of measured parameters determined based on measurement methods described herein can be communicated to a lithography tool to adjust the lithography system to achieve a desired output. In a similar way etch parameters (e.g., etch time, diffusivity, etc.) or deposition parameters (e.g., time, concentration, etc.) may be included in a measurement model to provide active feedback to etch tools or deposition tools, respectively. In some example, corrections to process parameters determined based on measured device parameter values and a trained measurement model may be communicated to a lithography tool, etch tool, or deposition tool.

As described herein, the term “critical dimension” includes any critical dimension of a structure (e.g., bottom critical dimension, middle critical dimension, top critical dimension, sidewall angle, grating height, etc.), a critical dimension between any two or more structures (e.g., distance between two structures), and a displacement between two or more structures (e.g., overlay displacement between overlaying grating structures, etc.). Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect, including measurement applications such as critical dimension metrology, overlay metrology, focus/dosage metrology, and composition metrology. However, such terms of art do not limit the scope of the term “metrology system” as described herein. In addition, the metrology system 100 may be configured for measurement of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the calibration of system parameters based on critical dimension data.

Various embodiments are described herein for a semiconductor measurement system that may be used for measuring a specimen within any semiconductor processing tool (e.g., an inspection system or a lithography system). The term “specimen” is used herein to refer to a wafer, a reticle, or any other sample that may be processed (e.g., printed or inspected for defects) by means known in the art.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO2. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A metrology system comprising:
at least one illumination source generating a first amount of broadband illumination light and a second amount of broadband illumination light;
an optical objective directing the first amount of broadband illumination light to a first measurement spot on a surface of a specimen under measurement and the second amount of broadband illumination light to a second measurement spot on the surface of the specimen under measurement and collecting a first amount of collected light from the first measurement spot in response to the first amount of broadband illumination light and a second amount of collected light from the second measurement spot in response to the second amount of broadband illumination light, wherein the first and second measurement spots are colocated, wherein the optical objective directs the first and second amounts of broadband illumination light to the first and second measurement spots, respectively, at one or more angles of incidence, one or more azimuth angles, or a combination thereof, and wherein a size of the first and second measurement spots on the surface of the specimen is at least 20 micrometers;
a Spectroscopic Reflectometer (SR) subsystem including:
an SR illumination optics subsystem directing the first amount of broadband illumination light from the at least one illumination source toward the optical objective;
at least one spectrometer having a surface sensitive to incident light, the at least one spectrometer detecting the first amount of collected light and generating SR spectral signals indicative of the first amount of collected light;
a SR collection optics subsystem directing the first amount of collected light from the optical objective to the at least one spectrometer;
a Pattern Recognition (PR) based imaging subsystem including:
an PR illumination optics subsystem directing the second amount of broadband illumination light from the at least one illumination source toward the optical objective;
at least one imaging detector having a surface sensitive to incident light, the at least one imaging detector detecting the second amount of collected light and generating PR image signals indicative of the second amount of collected light;
a PR collection optics subsystem directing the second amount of broadband illumination light from the optical objective to the at least one imaging detector; and
a computing system configured to generate an estimated value of at least one parameter of interest characterizing a structure disposed on the specimen under measurement based on the SR spectral signals and the PR image signals.

2. The metrology system of claim 1, wherein the first amount of broadband illumination light includes wavelengths spanning a range from 170 nanometers to 1,000 nanometers and the second amount of broadband illumination light includes wavelengths spanning a range from 400 nanometers to 1,300 nanometers.

3. The metrology system of claim 1, wherein the detecting of the first amount of collected light from the first measurement spot and the detecting of the second amount of collected light from the second measurement spot is simultaneous.

4. The metrology system of claim 1, wherein the detecting of the first amount of collected light from the first measurement spot involves detecting a plurality of spectra sequentially, wherein each of the plurality of spectra includes a different range of wavelengths, polarization states, or both.

5. The metrology system of claim 1, wherein the detecting of the second amount of collected light from the second measurement spot involves detecting a plurality of images sequentially, wherein each of the plurality of images includes a different range of wavelengths.

6. The metrology system of claim 1, wherein the detecting of the second amount of collected light from the second measurement spot involves detecting spectra associated with a first range of wavelengths, wherein the detecting of the second amount of collected light from the second measurement spot involves detecting one or more images associated with a second range of wavelengths different from the first range of wavelengths.

7. The metrology system of claim 6, wherein the estimating of the value of the at least one parameter of interest characterizing the structure disposed on the specimen under measurement involves estimating a value of a first parameter of interest based on the SR spectral signals and estimating a value of a second parameter of interest based on the PR image signals, wherein the first parameter of interest is associated with a portion of the structure located at a first depth from the surface of the specimen, and wherein the second parameter of interest is associated with a portion of the structure located at a second depth from the surface of the specimen.

8. The metrology system of claim 1, the structure disposed on the specimen under measurement is a hybrid bonding structure or a through silicon via.

9. The metrology system of claim 8, wherein the hybrid bonding structure is disposed on the backside of the specimen opposite the surface of the specimen illuminated by the first and second amounts of illumination light, and wherein a pitch characterizing a distance between adjacent instances of hybrid bonding pads of the hybrid bonding structure is 10 micrometers or less.

10. The metrology system of claim 1, wherein the at least one parameter of interest characterizing the structure disposed on the specimen under measurement includes overlay, surface profile, surface roughness, or any combination thereof.

11. The metrology system of claim 1, wherein the at least one imaging detector is a hyperspectral detector.

12. The metrology system of claim 1, wherein the at least one imaging detector is a two dimensional charge coupled device (CCD) sensitive to wavelengths spanning a range from 400 nanometers to 1,700 nanometers.

13. The metrology system of claim 1, further comprising:
a spectroscopic ellipsometry subsystem including:
an SE illumination optics subsystem directing a third amount of broadband illumination light generated by the at least one illumination source to a third measurement spot on the surface of the specimen under measurement;
and SE collection optics subsystem collecting a third amount of collected light from the third measurement spot in response to the third amount of broadband illumination light; and
at least one SE spectrometer having a surface sensitive to incident light, the at least one SE spectrometer detecting the third amount of collected light and generating SE output signals indicative of the third amount of collected light, wherein the computing system is further configured to generate an estimated value of the at least one parameter of interest characterizing the structure disposed on the specimen under measurement based on the SR spectral signals, the PR image signals, and the SE output signals.

14. The metrology system of claim 1, wherein the first amount of broadband illumination light includes wavelengths spanning a range from 170 nanometers to 2,500 nanometers and the second amount of broadband illumination light includes wavelengths spanning a range from 400 nanometers to 1,700 nanometers.

15. The metrology system of claim 1, wherein an illumination Numerical Aperture (NA) of the SR subsystem is between 0.04 and 0.08, and wherein a collection NA of the SR subsystem is between 0.01 and 0.04.

16. The metrology system of claim 1, wherein the estimating of the at least one parameter of interest involves a trained machine learning based measurement model having the SR spectral signals, the PR image signals, or both, as input to the trained machine learning based measurement model.

17. A method comprising:
generating a first amount of broadband illumination light and a second amount of broadband illumination light;
directing the first amount of broadband illumination light to a first measurement spot on a surface of a specimen under measurement and the second amount of broadband illumination light to a second measurement spot on the surface of the specimen under measurement;
collecting a first amount of collected light from the first measurement spot in response to the first amount of broadband illumination light and a second amount of collected light from the second measurement spot in response to the second amount of broadband illumination light by an optical objective, wherein the first and second measurement spots are colocated, and wherein a size of the first and second measurement spots on the surface of the specimen is at least 20 micrometers;
detecting the first amount of collected light on at least one spectrometer;
detecting the second amount of collected light on at least one imaging detector;
generating Spectroscopic Reflectometry (SR) output signals indicative of the detected first amount of collected light;
generating Pattern Recognition (PR) image signals indicative of the detected second amount of collected light; and
determining an estimated value of at least one parameter of interest characterizing a structure disposed on the specimen under measurement based on the SR spectral signals and the PR image signals.

18. The method of claim 17, wherein the first amount of broadband illumination light includes wavelengths spanning a range from 170 nanometers to 1,000 nanometers and the second amount of broadband illumination light includes wavelengths spanning a range from 400 nanometers to 1,300 nanometers.

19. The method of claim 17, wherein the detecting of the second amount of collected light from the second measurement spot involves detecting a plurality of images sequentially, wherein each of the plurality of images includes a different range of wavelengths.

20. A metrology system comprising:
at least one illumination source generating a first amount of broadband illumination light and a second amount of broadband illumination light;
an optical objective directing the first amount of broadband illumination light to a first measurement spot on a surface of a specimen under measurement and the second amount of broadband illumination light to a second measurement spot on the surface of the specimen under measurement and collecting a first amount of collected light from the first measurement spot in response to the first amount of broadband illumination light and a second amount of collected light from the second measurement spot in response to the second amount of broadband illumination light, wherein the first and second measurement spots are colocated, and wherein a size of the first and second measurement spots on the surface of the specimen is at least 20 micrometers;
a Spectroscopic Reflectometer (SR) subsystem including:
an SR illumination optics subsystem directing the first amount of broadband illumination light from the at least one illumination source toward the optical objective;
at least one spectrometer having a surface sensitive to incident light, the at least one spectrometer detecting the first amount of collected light and generating SR spectral signals indicative of the first amount of collected light;
a SR collection optics subsystem directing the first amount of collected light from the optical objective to the at least one spectrometer;
a Pattern Recognition (PR) based imaging subsystem including:
an PR illumination optics subsystem directing the second amount of broadband illumination light from the at least one illumination source toward the optical objective;
at least one imaging detector having a surface sensitive to incident light, the at least one imaging detector detecting the second amount of collected light and generating PR image signals indicative of the second amount of collected light;
a PR collection optics subsystem directing the second amount of broadband illumination light from the optical objective to the at least one imaging detector; and
a non-transitory computer readable medium comprising instructions that, when executed by one or more processors, causes the one or more processors to:
generate an estimated value of at least one parameter of interest characterizing a structure disposed on the specimen under measurement based on the SR spectral signals and the PR image signals.
